(19) United States
(12) Patent Application Publication
(10) Pub. No.: US 2025/0376784 A1
(43) Pub. Date: Dec. 11, 2025

(54) METHOD FOR PREPARING COMPOUND CRYSTAL VIA MELT MIGRATION UNDER SUPERGRAVITY

(71) Applicant: THE 13TH RESEARCH INSTITUTE OF CHINA ELECTRONICS TECHNOLOGY GROUP CORPORATION, Shijiazhuang, Hebei (CN)

(72) Inventors: Shujie Wang, Shijiazhuang, Hebei (CN); Niefeng Sun, Shijiazhuang, Hebei (CN); Junyan Huai, Shijiazhuang, Hebei (CN); Senfeng Xu, Shijiazhuang, Hebei (CN); Yanlei Shi, Shijiazhuang, Hebei (CN); Huimin Shao, Shijiazhuang, Hebei (CN); Zheng Liu, Shijiazhuang, Hebei (CN); Jiping Dang, Shijiazhuang, Hebei (CN); Xiaolan Li, Shijiazhuang, Hebei (CN); Yang Wang, Shijiazhuang, Hebei (CN); Huisheng Liu, Shijiazhuang, Hebei (CN)

(21) Appl. No.: 19/101,238

(22) PCT Filed: Dec. 14, 2022
(86) PCT No.: PCT/CN2022/138864

§ 371 Date: Feb. 4, 2025

(30) Foreign Application Priority Data
Aug. 5, 2022 (CN) 202210938176.6

(51) Int. Cl. C30B 9/06; C30B 29/40

(52) U.S. Cl. CPC C30B 9/06; C30B 29/40

(57) ABSTRACT

A method for preparing a compound crystal via melt migration under supergravity. The method comprises: sequentially placing compound semiconductor poly crystals having a molecular formula of AxBy, an elementary substance of an element A, and seed crystals in a crucible in a close contact manner, and horizontally placing the crucible on a centrifugal rotating device; heating the crucible to T₀, 800° C.<T₀<Tₘ; starting the centrifugal rotating device, so that a centrifugal force G is greater than 100 g; after applying the centrifugal force, elements A and B in a melt moving towards two sides of a molten pool, dissolving the polycrystals, and the seed crystals starting to grow a single crystal; and along with continuous dissolution of the polycrystals and continuous growth of the single crystal, the melt migrating towards the polycrystals, thereby achieving single crystal preparation.

### FIELD

The present invention relates to the field of semiconductor preparation and, in particular, to a method of preparing compound single crystals by inducing melt migration under supergravity, especially under centrifugal force.

### BACKGROUND

Compound semiconductors are semiconductor materials composed of two or more elements. They are characterized by high saturation velocity, easily tunable energy bands, and wide bandgaps, offering unique advantages in high-power and high-frequency applications. They hold an irreplaceable position in industries such as wireless communication, power electronics, and fiber-optic communication.

In the current technology, traditional melt methods such as vertical Bridgman method, vertical temperature gradient solidification method, guided mold method, and Czochralski method are used for growing large crystals of aluminum oxide, gallium arsenide, indium phosphide, and gallium oxide. Physical vapor transport method and metal organic chemical vapor deposition are used for growing compound semiconductors such as silicon carbide and gallium nitride. However, the above methods are costly and inefficient.

The melt method is the most cost-effective and efficient method for crystal preparation. However, due to certain characteristics of some compound semiconductors, such as high melting points and high saturated vapor pressures, the melt method can either become costly or difficult to implement. Non-stoichiometric melts can reduce the high saturated vapor pressure and lower the crystallization point of the melt. However, controlling the growth interface of non-stoichiometric melts is highly challenging, and as growth progresses, the compositional ratio tends to deviate further, making crystal preparation significantly more difficult.

### SUMMARY

To overcome the deficiencies of the prior art, the present invention has been proposed.

The technical solution adopted in the present invention is: a method of preparing compound crystals by melt migration under supergravity, including the following steps:
The polycrystal compound semiconductor with the molecular formula AxBy, pure element A, and seed crystals are placed in close contact, sequentially arranged inside a crucible. The crucible is then horizontally positioned on a centrifugal rotation device;
The crucible is heated to T₀, where 800° C.<T₀<Tₘ, with Tₘ being the melting point of the compound semiconductor AxBy, and T₀ being higher than the melting point of element A;
Element A melts to form a liquid melt, occupying a space that creates a molten pool. The contact surface between the melt and the seed crystals forms Interface I, while the contact surface between the melt and the polycrystals forms Interface II;
At Interface I, the melt dissolves the seed crystals, and at Interface II, the melt dissolves the polycrystals. This process ultimately forms a non-stoichiometric melt containing elements A and B, continuing until the equilibrium composition at the given temperature is reached. The composition within the melt is denoted as C;
Activate the centrifugal rotation device to generate a centrifugal force G greater than 100 g;
After applying the centrifugal force, elements A and B within the melt move toward two sides of the molten pool: the element that raises the liquid-solid equilibrium temperature moves toward Interface I, while the element that lowers the liquid-solid equilibrium temperature moves toward Interface II, and the composition in the middle and on both sides of the melt changes;
Due to the differences in composition, the liquid-solid equilibrium temperatures at the two interfaces vary: at Interface II, an overheating degree ΔTh is generated, causing the polycrystals to continue dissolving; at Interface I, an overcooling degree ΔTc is generated, prompting the seed crystal to begin growing into a single crystal; as the polycrystals continuously dissolves and the single crystal keeps growing, the melt migrates toward the polycrystals, enabling the preparation of the single crystal.

Existing studies show that supergravity, as an enhanced separation method, can facilitate the separation of elements in alloys. This approach can be used to purify materials and refine the solidification structure of two types of alloys.

Yang Yuhou, in “Fundamental Research on the Refinement of Metal Solidification Structure and Element Segregation Behavior under Hypergravity,” disclosed that under a supergravity field of G=70 g, carbon (C) separation occurred in the Fe—C alloy, and the austenite grains in Fe-0.99 wt % C low-carbon steel were significantly refined.

Centrifugal force is a means of generating supergravity.

In this invention, one of the elements that constitutes the compound semiconductor is placed between the seed crystals and the polycrystals. The system is heated, and centrifugal force is applied. This element melts and partially dissolves the seed crystals and the polycrystals, forming a non-stoichiometric melt. Centrifugal force causes the element that lowers the liquid-solid equilibrium temperature to become enriched on the polycrystals side, leading to its dissolution; the element that raises the liquid-solid equilibrium temperature moves toward the single-crystal side. As the crystallization point of the melt increases, overcooling occurs, triggering the growth of the seed crystals and expelling the other element into the melt, thereby maintaining a constant composition in the molten pool. This process, accompanied by melt migration, continuously achieves single-crystal growth and polycrystals melting, ultimately enabling single-crystal preparation. This method is applicable to the preparation of compound semiconductors such as gallium oxide, silicon carbide, indium phosphide, and gallium arsenide.

Beneficial Effects: The method proposed in this invention allows for the rapid growth of single crystals at a temperature lower than the melting point of the compound semiconductor. It increases the critical shear stress at the growth interface and reduces dislocation density. At the same time, lowering the melting point also reduces the saturated vapor pressure of the melt, thereby reducing the requirements for pressure equipment and growth conditions. Furthermore, it enables the efficient growth of crystals using the melt method, even for those previously unsuitable for this technique.

### BRIEF DESCRIPTION OF THE DRAWINGS

FIG. 1 is an assembly diagram of the device used in this invention.

FIG. 2 is a schematic diagram of the seed crystal crucible.

FIG. 3 is a schematic diagram of the growth crucible.

FIG. 4 is an assembly diagram of the crucible.

FIG. 5 is a schematic diagram of this invention.

FIG. 6 is a schematic diagram of melt migration during the crystal growth process.

FIG. 7 is a schematic diagram after the completion of single-crystal growth.

1: seed crystal; 2: polycrystal; 3: element A; 3-1: Interface I; 3-2: Interface II; 4: heating wire; 5: furnace side plate; 6: furnace barrel; 7: insulation layer; 8: thermocouple I; 9: thermocouple II; 10: thermocouple III; 11: thermocouple connecting line; 12: outer top block; 13: inner cushion block; 14: growth crucible; 14-1: growth zone; 14-2; 14-3 crucible wall; crucible base; 15: seed crystal crucible; 15-1: cover layer; 15-2: seed crystal hole; 15-3: platform; 15-4: connection zone; 15-5: seed crystal cover; 16: centrifugal rotation motor; 17: centrifugal main shaft; 18: slider I; 19: slider II; 20: connecting rod; 21: polycrystalline fragments; 22: molten pool; 23: gas inlet/outlet pipeline.

### DETAILED DESCRIPTION

A method for preparing compound crystals through melt migration under supergravity involves using a compound semiconductor polycrystal with the molecular formula AxBy, pure elemental A, and a seed crystal to produce single crystals.

The compound semiconductor AxBy, where A is an element and B is an element, with x and y representing the stoichiometric ratio of the semiconductor, such as indium phosphide (InP), gallium oxide (Ga₂O₃), or silicon carbide (SiC). The purpose of using the pure elemental A is to form a low-melting-point melt, which dissolves the polycrystal and single-crystal compounds, and, under the influence of centrifugal force, the elements A and B in the non-stoichiometric melt are redistributed, lowering the melting temperature at the polycrystal interface and increasing the growth temperature at the single crystal interface, thereby enabling the preparation of single crystals.

According to the naming rules of chemical formulas, in AxBy, A is a metal element such as gallium or indium, or a semiconductor element such as silicon or germanium. B is a non-metal element, such as oxygen, carbon, phosphorus, or arsenic.

In principle, the use of either pure element A or B can achieve the aforementioned goals. However, B may be a gaseous element such as oxygen or a high-melting-point element like carbon, both of which are unsuitable. In this invention, pure element A is used to enable the preparation of single crystals.

In the present invention, element A is a metal element or non-metal element with a melting point below 2000° C. and low volatility, such as In, Ga, Al, Si, Ge, etc.

The method includes the following steps: placing the compound semiconductor polycrystal with the molecular formula AxBy, pure element A, and the seed crystal in close contact, sequentially arranged inside the crucible. Position the crucible horizontally on the centrifugal rotation equipment.

Heating the crucible to a temperature T₀, where 800° C.<T₀<Tₘ, with Tₘ being the melting point of the compound semiconductor AxBy, and T₀ higher than the melting point of element A.

Element A melts to form a melt, the space occupied by the melt forms a molten pool. The contact surface between the melt and the seed crystal forms Interface I, the contact surface between the melt and the polycrystal forms Interface II. Initially, the melt contains only element A.

At Interface I, the melt dissolves the seed crystals, and at Interface II, the melt dissolves the polycrystal. and the melt contains element A and element B, ultimately forming a non-stoichiometric melt composed of A and B. This process continues until the melt reaches its equilibrium composition at the given temperature, with the composition of the melt denoted as C₀.

At this time, if the temperature remains unchanged and the melt remains static, the liquid-solid transition equilibrium temperature of interface I, interface II and the middle of the melt is the same, equilibrium can be achieved, and the melt no longer dissolves seed crystals or polycrystals.

“Liquid-solid transition equilibrium temperature”: the melting point and crystallization point of the compound. The content of elements A and B affects the melting point and crystallization point of the melt (“liquid-solid transition equilibrium temperature”).

The melt temperature is different, the elemental composition would be different at equilibrium. If the temperature is Tₘ, the content of each element in the melt is the ratio in the molecular formula; if the temperature is set to T₀, the composition in the melt is represented as C. Different compositions have different liquid-solid transition equilibrium temperatures.

Setting the temperature T₀ also determines the composition of the melt at this temperature, and at the same time determines the liquid-solid transition equilibrium temperature of the melt to be T₀.

The above-mentioned “dissolution” can also be expressed as “erosion”, which can be compared to water dissolving solid sugar or salt.

Start the centrifugal rotating device and gradually increase the rotational speed at an acceleration of 5-50 rad/s² until the centrifugal force G is greater than 100 g.

Under the influence of centrifugal force, elements A and B of different densities move towards two sides of the molten pool. By setting the position of the seed crystals and the polycrystal relative to the centrifugal rotational axis, the following is achieved: the element that increases the liquid-solid transition equilibrium temperature move towards interface I, and the element that decreases the liquid-solid transition equilibrium temperature move towards interface II, and the composition of the melt in the middle and on both sides of the molten pool changes.

Due to the difference in composition, the liquid-solid transition equilibrium temperatures at the two interfaces are different:

At Interface II, the actual temperature is T₀. The movement of the elements causes the liquid-solid phase transition equilibrium temperature to decrease, creating an overheating degree ΔTₕ. This causes the polycrystal to continue to dissolve.

At interface I, the actual temperature is T₀. The movement of the elements causes the liquid-solid transition equilibrium temperature to increase, creating a overcooling ΔT_{c}. This causes the seed crystal to continue to grow into a single crystal.

As the polycrystal is continuously dissolved and the single crystal is continuously grown, the melt migrates toward the polycrystal, achieving single crystal preparation.

The melt in the molten pool contains two elements A and B. One of the key points of the present invention is to increase the liquid-solid transition equilibrium temperature of the interface between the seed crystal and the melt and reduce the liquid-solid transition equilibrium temperature of the interface between the polycrystal and the melt. This requires setting the position of the seed crystal and the polycrystal relative to the centrifugal rotation axis according to the characteristics of the elements.

There are 4 scenarios, as shown in the following table:

| | | |
|---|---|---|
| 1 | In the A-B melt system, the increase of element A | The seed crystals are close to |
| | lowers the melting point, the increase of element B | the centrifugal rotation axis, |
| | raises the melting point, and the density of element A | and the polycrystal is far |
| | is greater than that of element B | away from the centrifugal |
| | | rotation axis |
| 2 | In an A-B melt system, the increase of element A | The polycrystal is close to the |
| | lowers the melting point, while the increase of element | centrifugal rotation axis, and |
| | B raises the melting point, and the density of element | the seed crystals are far away |
| | A is less than that of element B | from the centrifugal rotation |
| | | axis |
| 3 | In the A-B melt system, the increase of element A | The polycrystal is close to the |
| | increases the melting point, the increase of element B | centrifugal rotation axis, and |
| | decreases the melting point, and the density of element | the seed crystals are far away |
| | A is greater than that of element B | from the centrifugal rotation |
| | | axis |
| 4 | In the A-B melt system, the increase of element A | The seed crystals are close to |
| | increases the melting point, the increase of element B | the centrifugal rotation axis, |
| | decreases the melting point, and the density of element | and the polycrystal is far |
| | A is less than that of element B. | away from the centrifugal |
| | | rotation axis |

This invention also proposes a specialized device to implement the method of preparing compound crystals through melt migration under supergravity.

Referring to FIG. 1, the device includes a centrifugal rotating motor 16, a centrifugal main shaft 17 connected to the centrifugal rotating motor 16, a horizontally positioned connecting rod 20 connected to the centrifugal main shaft 17, and a crystal growth device connected to the connecting rod 20.

The crystal growth device includes a furnace side plate 5 connected to a connecting rod 20, a furnace barrel 6 connected to the furnace side plate 5 and forming a sealed space, a thermal insulation layer 7 is arranged close to the furnace barrel 6 in the sealed space, combination crucibles and heating wires 4 around the combination crucible are placed in the thermal insulation layer 7, and an outer top block 12 and an inner cushion pad 13 are respectively arranged at both ends of the combination crucible; the crystal growth device is positioned horizontally.

The combination crucible includes a growth crucible 14 and a seed crystal crucible 15 which are horizontally positioned and joined together.

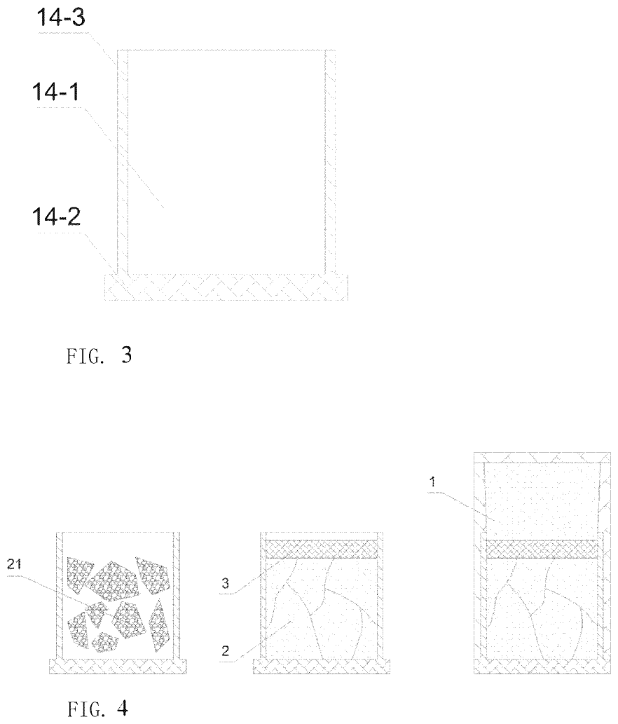

Referring to FIG. 3, the growth crucible 14 includes a crucible base 14-2 and a crucible wall 14-3 forming a growth zone 14-1.

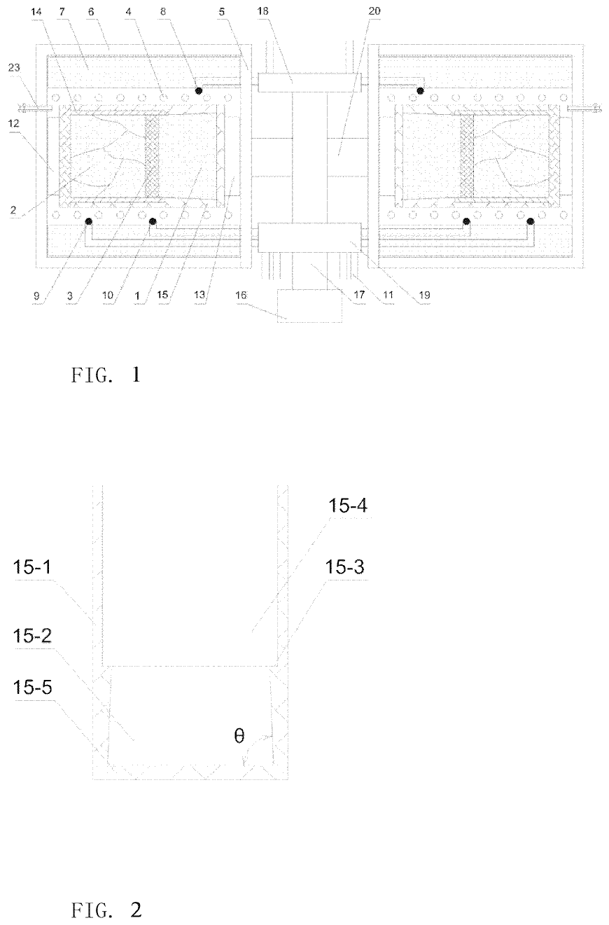

Referring to FIG. 2, the seed crystal crucible 15 includes a cover layer 15-1, a seed crystal cover 15-5 connected to the cover layer 15-1, and a platform 15-3 inside the cover layer 15-1. The space between the platform 15-3 and the seed crystal cover 15-5 is seed crystal hole 15-2, and the space above the platform 15-3 is a connection zone 15-4. The angle θ between the seed crystal cover 15-5 and the cover layer 15-1 is between 70° and 85°, which fits the seed crystal, preventing the seed crystal from moving around.

The inner diameter of the cover layer 15-1 is larger than the outer diameter of the crucible wall 14-3, with the difference between the two diameters being less than 2 mm, allowing the two to be tightly fitted.

The device also includes thermocouple I 8, thermocouple II 9, and thermocouple III 10 positioned on the side of the combination crucible. The thermocouple I 8 derives a signal through a thermocouple connecting line 11 via furnace side plate 5 and slider I 18 connected to centrifugal main shaft 17. The thermocouple II 9 and the thermocouple III 10 derive a signal through furnace side plate 5 and slider II 19 connected to centrifugal main shaft 17.

2-4 crystal growth devices are evenly arranged around the centrifugal main shaft 17.

For example, in the case of indium phosphide (InP), the density of indium is greater than that of phosphorus. In an indium-phosphorus melt, increasing the amount of indium lowers the liquid-solid phase transition equilibrium temperature of the melt, while increasing the amount of phosphorus raises the liquid-solid phase transition equilibrium temperature of the melt.

The specific steps for using the above device to achieve the method of preparing compound crystals by melt migration under supergravity are as follows:

### Step 1,

1. Put the indium phosphide polycrystalline fragments 21 in the growth crucible 14, heat the material to melt it and cool it down to solidify it into indium phosphide polycrystals 2, the purpose is to make the polycrystals 2 and the growth crucible 14 be in close contact, to prevent the centrifugal force in the subsequent steps from squeezing the melt 3 in the molten pool 22 into any gaps.

Place elemental A (3), which, in this embodiment, is indium, on the surface of the polycrystals (2). Elemental A (3) is in the shape of a disk, with its outer diameter the same as the inner diameter of the growth crucible (14).

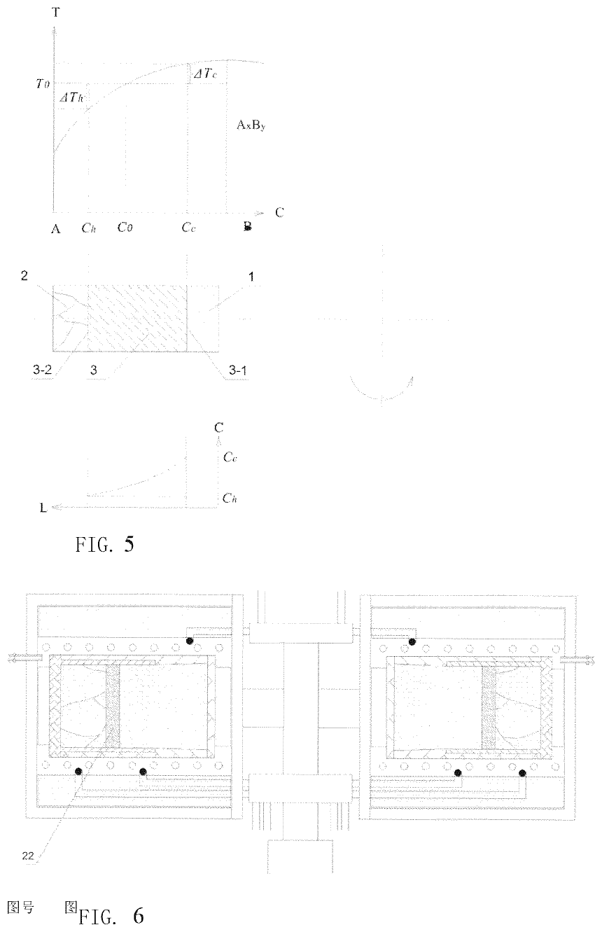

Assemble the inner surface of the cover layer 15-1 in the seed crystal crucible 15 with the outer surface of growth zone 14-1 of the growth crucible 14. The top of the crucible wall 14-3 rests against the platform 15-3. Place the seed crystals 1 into the seed crystal hole 15-2, and use the seed crystal cover 15-5 to seal the seed crystal hole 15-2. The growth crucible 14 and the seed crystal crucible 15 form a combination crucible, as shown in FIG. 4.
2. Place the combined crucible into the furnace barrel 6 and fix the combined crucible using the outer top block 12 and inner cushion block 13.

The external part of the combined crucible is surrounded by heating wires 4, and the heating wires are covered by an insulating layer 7. Thermocouple I 8, thermocouple II 9, and thermocouple III 10 are arranged through the insulating layer 7, with their temperature sensing tips passing through the inner wall of the insulating layer 7 and approaching the outer wall of the combination crucible.

The thermocouple II 8 exports the temperature signal through the furnace side plate 5 connected to the slider I 18. Thermocouple II 9 and thermocouple III 10 export temperature signals through the furnace side plate 5 connected to the slider II 9.

The above steps complete the assembly of the crystal growth device. There can be 2-4 crystal growth devices. In this embodiment, two crystal growth devices are assembled.
3. Fix the furnace barrel 6 to the furnace side plate 5, and fix the furnace side plate 5 to the connecting rod 20, and the connecting rod 20 is connected to the centrifugal main shaft 17.

The two crystal growth devices are symmetrically arranged on two sides of the centrifugal main shaft 17. If there are more than two, they are evenly arranged around the centrifugal main shaft 17.

Since the density of indium is greater than that of phosphorus, adding indium to the phosphorus-indium melt lowers the liquid-solid phase transition equilibrium temperature. Therefore, in this example, the placement of the combination crucible positions the seed crystals 1 closer to the centrifugal main shaft 17.

The above process completes the assembly of the device, as shown in FIG. 1.

The furnace space formed by the furnace barrel 6 and the furnace side plate 5 is evacuated to 100 Pa using the gas inlet/outlet pipeline 23. Then, inert gas is introduced, increasing the pressure to 3 MPa-4 MPa.

The combined crucible is heated using the heating wire (4), and the temperature is monitored through thermocouples I (8), II (9), and III (10). The temperature is raised to T₀.

Theoretically, crystal growth can be achieved as long as T₀ is higher than the melting point of element A. Under the same centrifugal force, a higher T₀ results in faster crystal growth, whereas if T₀ is too low, the growth process will be significantly slower. Therefore, in this example, T₀ is restricted to the range 800° C.<T₀<Tₘ.

The single substance 3 of element A (in this embodiment, indium) melts into a melt, and the space occupied forms a molten pool 22. The melt dissolves part of the seed crystal 1 and the polycrystal 2, forming a non-stoichiometric binary melt containing indium and phosphorus in the molten pool. The binary melt composition is referred to as C₀, and forms an interface I 3-1 between the seed crystal 1 and the melt and an interface II 3-2 between the polycrystal 2 and the melt.

Step 2, start the centrifugal rotating motor 16 to drive the rotation of the furnace barrel 6, and gradually increase the rotational speed at a rate of 5-50 rad/s² until the centrifugal force G is greater than 100 g.

The centrifugal force G is usually expressed in multiples of g (acceleration due to gravity). The conversion formula between G and the rotational speed is as follows:
G=1.11×10⁻⁵×R×ω2×g, G is the centrifugal force, ω is the rotational speed in rpm, and R is the radius in centimeter.

In this embodiment, the radius R can be regarded as the distance from the furnace side plate 5 to the centrifugal main shaft 17.

The rotation speed of the centrifugal rotating motor 16 can be calculated by the above formula.

Experiments show that a centrifugal force G of 50 g can cause the separation of elements in the melt. To speed up the separation of elements and thus increase the synthesis speed, G is set to 100 g in this embodiment.

Under the action of centrifugal force, the indium element in the melt within the molten pool 22 moves toward the side of the polycrystal 2, and the composition of the melt at the interface II 3-2 reaches Cₕ, creating a degree of overheating ΔTₕ, causing the polycrystal 2 to dissolve; the phosphorus element in the melt within the molten pool 22 moves toward the side of the single crystal 1, and the composition of the melt at the interface I 3-1 reaches C_{c}, creating a degree of overcooling ΔT_{c}, causing the seed crystal 1 to begin to grow a single crystal and discharge the indium element into the melt, as shown in FIG. 5.

In FIG. 5, the horizontal axis of the upper coordinate system represents the composition C, the vertical axis represents the temperature T, and the curve in the figure represents the liquid-solid transition equilibrium temperature at different compositions in the melt; the horizontal axis of the lower coordinate system is position L, the starting position of which is the bottom of the seed crystal 1, the vertical axis is the composition C, and the curve in the figure is the composition of the melt at different positions in the molten pool 22. The direction of the horizontal axis of this figure is set in the opposite direction compared to conventional settings. If the position of the crystal seed 1 is different, the starting position and direction of the horizontal axis would change accordingly.

In this embodiment, the proportion of element A (in this embodiment, indium) in the melt is Cₕ>C₀>C_{c}, and the proportion of element B (in this embodiment, phosphorus) in the melt is Cₕ<C₀<C_{c}. As a result, the melts at different positions of the molten pool 22 contain different compositions and have different liquid-solid transition equilibrium temperatures. The melt with component C₀ has a liquid-solid transition equilibrium temperature of T₀, the melt with component Cₕ has a liquid-solid transition equilibrium temperature less than T₀, and the melt with component C_{c} has a liquid-solid transition equilibrium temperature greater than T₀.

As the polycrystal 2 is continuously dissolved and the crystal grows continuously, the molten pool 22 migrates toward the polycrystal 2, finally achieving single crystal preparation.

In this embodiment. During this process, the seed crystal 1 grows away from the centrifugal main shaft 17, as shown in FIG. 6.

3-5 groups of experiments are conducted, and the samples were removed at 1 hour, 2 hours, and 3 hours respectively, and the moving speed of the test interface I 3-1 is tested; the single crystal growth time is determined according to the moving speed and the amount of material.

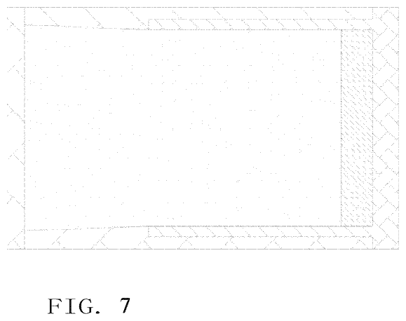

Step 3, repeat the operations of steps 1-2, and complete the single crystal preparation according to the sample single crystal growth time, as shown in FIG. 7. After the growth is completed, the device is removed, and the single crystal is taken out.

1. A method for preparing compound crystals by melt migration under supergravity, characterized in that,
the method comprises the following steps:
placing a compound semiconductor polycrystal with molecular formula AxBy, a pure element A, and a seed crystal in close contact, sequentially arranged within a crucible, and positioning the crucible horizontally on a centrifugal rotation device;
heating the crucible to T₀, where 800° C.<T₀<Tₘ, Tₘ being a melting point of the compound semiconductor AxBy, and T₀ being greater than a melting point of element A;
the element A melts to form a melt, and the space occupied by the melt forms a molten pool; a contact surface between the melt and the seed crystal forms interface I, a contact surface between the melt and the polycrystal forms interface II;
at interface I, the melt dissolves the seed crystal, and at interface II, the melt dissolves the polycrystal, ultimately forming a non-stoichiometric melt containing element A and element B, until it reaches an equilibrium composition at a given temperature; a composition in the melt is C₀;
starting the centrifugal rotation device, ensuring that a centrifugal force G exceeds 100 g;
after applying centrifugal force, elements A and B in the melt moving toward two sides of the melt pool: wherein the element that increases the liquid-solid phase transition equilibrium temperature moves toward interface I, the element that decreases the liquid-solid phase transition equilibrium temperature moves toward interface II, causing changes in a middle and two sides of the composition of the melt;
due to differences in composition, the liquid-solid phase transition equilibrium temperatures at the two interfaces differ: at interface II, an overheating degree ΔTₕ is generated, causing the polycrystal to continue dissolving; at interface I, an overcooling degree ΔT_{c} is generated, causing the seed crystal to begin to grow into a single crystal;
as the polycrystal continues to dissolve and the single crystal continues to grow, the melt migrates toward the polycrystal, achieving single crystal formation.

2. The method according to claim 1, characterized in that,
if a density of element A is greater than that of element B and an increase of element A will reduce the liquid-solid transition equilibrium temperature of the melt, or if the density of element A is less than that of element B and the increase of element A will increase the liquid-solid transition equilibrium temperature of the melt, the seed crystal is placed closer to a rotation axis of the centrifugal rotating device; otherwise, the polycrystal is placed closer to the rotation axis of the centrifugal rotating device.

3. The method according to claim 1, characterized in that:
the method is implemented by using a device for preparing compound crystals driven by centrifugal force, the device comprising a centrifugal rotating motor, a centrifugal main shaft connected to the centrifugal rotating motor, a horizontally positioned connecting rod connected to the centrifugal main shaft, and a crystal growth device connected to the connecting rod;
the crystal growth device is placed horizontally, comprising a furnace side plate connected to the connecting rod, a furnace barrel connected to the furnace side plate to form a sealed space, a thermal insulation layer is placed close to the furnace barrel in the sealed space, a combination crucible placed within the heat insulation layer surrounded by heating wires; the combination crucible has an outer top block and an inner cushion block at each end;
the combination crucible includes horizontally placed growth crucible and seed crystal crucible, integrated with each other;
the growth crucible includes a crucible base and a crucible wall forming a growth zone;
the seed crystal crucible includes a cover layer, a seed crystal cap connected to the cover layer, and a platform inside the cover layer; a space from the platform to the seed crystal cap is a seed crystal hole, and the space above the platform is the connection area.

4. The method according to claim 3, characterized in that
an angle (θ) between the seed crystal cover and the cover layer is between 70° and 85°.

5. The method according to claim 3, characterized in that
the device also includes a thermocouple I, a thermocouple II and a thermocouple III arranged on a side of the combination crucible.

6. The method according to claim 3, characterized in that
there are 2-4 crystal growth devices, which are evenly arranged around the centrifugal master shaft.

7. The method according to claim 6, characterized in that
the method comprises:
step 1, placing polycrystalline fragments of the compound semiconductor with the molecular formula AxBy into the growth crucible; heating the polycrystalline fragments until they melt, cooling it to solidify into polycrystal, ensuring that the polycrystal is in close contact with the growth crucible; placing element A on a surface of the polycrystal;
assembling an inner surface of the cover layer of the seed crystal crucible with an outer surface of the growth zone of the growth crucible; placing the seed crystal into the seed crystal hole and cover the seed crystal hole with the seed crystal cover; the growth crucible and the seed crystal crucible together form a combination crucible;
placing the combined crucible into the furnace barrel and securing it using the outer top block and the inner cushion gasket; fixing the furnace barrel to the furnace side plate, and fixing the furnace side plate to the connecting rod;
evacuating a furnace body space formed by the furnace barrel and the furnace side plate to 100 Pa, and then fill the furnace body space with inert gas to a pressure of 3 MPa-4 MPa;
heating the combination crucible by the heating wire to a temperature T₀;
step 2, starting the centrifugal rotating motor to drive the furnace barrel to rotate, gradually increasing the speed with an acceleration of 5-50 rad/s² until the centrifugal force G is greater than 100 g;
step 3, after the growth is completed, disassembling the device and removing the single crystal.

8. The method according to claim 7, characterized in that:
element A is in the shape of a disk, and its outer diameter is the same as the inner diameter of the growth crucible.

9. The method according to claim 7, characterized in that:
in step 1, if a density of element A is greater than that of element B, and an increase of element A will reduce the liquid-solid transition equilibrium temperature of the melt, or if the density of element A is less than that of element B, and the increase of element A will increase the liquid-solid transition equilibrium temperature of the melt, placing the seed crystal crucible of the combination crucible close to the centrifugal main shaft;
if not, placing the growth crystal crucible of the combination crucible close to the centrifugal main shaft.
